(19) United States
(12) Patent Application Publication
(10) Pub. No.: US 2024/0013967 A1
(43) Pub. Date: Jan. 11, 2024

(54) POWER SUPPLY DEVICE

(71) Applicant: YAZAKI CORPORATION, Tokyo (JP)

(72) Inventor: Tsunehiro Watanabe, Makinohara-shi (JP)

(21) Appl. No.: 18/474,126

(22) Filed: Sep. 25, 2023

Related U.S. Application Data
(63) Continuation of application No. PCT/JP2022/038489, filed on Oct. 14, 2022.

(30) Foreign Application Priority Data
Nov. 15, 2021 (JP) 2021-185739

(51) Int. Cl. H01F 27/28; H02M 3/00

(52) U.S. Cl. CPC H01F 27/2804; H02M 3/003; H01F 2027/2809

(57) ABSTRACT

A power supply device includes: an electronic component unit having a voltage conversion function that converts an input voltage into a target voltage and outputs the converted voltage; and a circuit board on which the electronic component unit is mounted. The electronic component unit includes an inductor portion configured such that a first turning portion configured by a conductor pattern divided and wired into the plurality of layers to have a spirally turning shape, and a second turning portion configured by a conductor pattern divided and wired into the plurality of layers to have a shape that spirally turns in a direction opposite to that of the first turning portion, are arranged adjacent to each other in a direction along a board surface of the circuit board, and a common input is made to an input end of the first turning portion and that of the second turning portion.

### CROSS-REFERENCE TO RELATED APPLICATIONS

This is a continuation of International Application No. PCT/JP2022/038489 filed on Oct. 14, 2022, and claims priority from Japanese Patent Application No. 2021-185739 filed on Nov. 15, 2021, the entire content of which is incorporated herein by reference.

### TECHNICAL FIELD

The present invention relates to a power supply device including an electronic component unit having a voltage conversion function that converts an input voltage into a predetermined target voltage and outputs the converted voltage, and a circuit board on which the electronic component unit is mounted.

### BACKGROUND ART

In the related arts, a DC/DC converter has been used for the purpose of power conversion between a battery and an inverter mounted in a vehicle such as a hybrid vehicle (for example, refer to Patent Literature 1). The DC/DC converter generally incorporates various inductors for the purpose of smoothing current after power conversion processing, removing noise, and the like.

### CITATION LIST

### Patent Literature

Patent Literature 1: JP2019-193517A

### SUMMARY OF INVENTION

### Technical Problem

Incidentally, in general, noise (so-called radiation noise) is generated due to the transmission of the magnetic field generated in the inductor to the surrounding space during operation of the inductor of the type described above. In particular, it is known that when switching control is performed at high current and high frequency as in a switching type DC/DC converter, the radiation noise of the inductor increases. The radiation noise of the inductor can also cause interference with proper operation of other electronic components in the DC/DC converter, or the like. Therefore, it is desirable to reduce the radiation noise in the inductor as much as possible.

One object of the present invention is to provide a power supply device having an inductor capable of reducing radiation noise.

### Solution to Problem

According to an aspect of the present invention, there is provided a power supply device including:
an electronic component unit having a voltage conversion function that converts an input voltage into a predetermined target voltage and outputs the converted voltage; and a circuit board on which the electronic component unit is mounted, in which
the circuit board has, at least at a part thereof, a multilayer structure in which a plurality of layers are stacked in a thickness direction of the circuit board, and
the electronic component unit includes an inductor portion configured such that a first turning portion configured by a conductor pattern divided and wired into the plurality of layers to have a spirally turning shape, and a second turning portion configured by a conductor pattern divided and wired into the plurality of layers to have a shape that spirally turns in a direction opposite to that of the first turning portion, are arranged adjacent to each other in a direction along a board surface of the circuit board, and a common input is made to an input end of the first turning portion and an input end of the second turning portion.

### BRIEF DESCRIPTION OF DRAWINGS

FIG. 1 is a functional block diagram of an electronic component unit included in a power supply device according to an embodiment of the present invention.

FIG. 2 is a perspective view, before lamination, of a location corresponding to an inductor portion of a circuit board having a multilayer structure included in the power supply device according to the embodiment of the present invention.

FIG. 3 is a top view of a location corresponding to the inductor portion of the power supply device according to the embodiment of the present invention.

### DESCRIPTION OF EMBODIMENTS

A power supply device 1 according to an embodiment of the present invention will be described below with reference to the drawings. The power supply device 1 is typically used by being mounted on a vehicle such as a hybrid vehicle. The power supply device 1 includes a switching type DC/DC converter, and has a voltage conversion function that converts an input voltage (for example, 240 V) from a drive battery (lithium ion battery and the like) for driving a vehicle drive motor mounted on the vehicle into a voltage (for example, 12 V) of a battery for driving on-vehicle electrical components mounted on the vehicle and outputs the converted voltage.

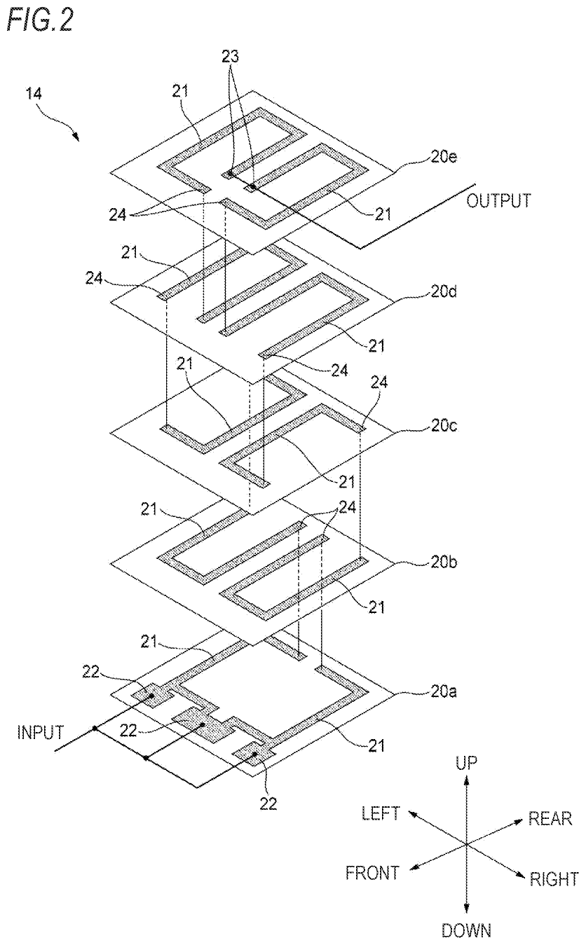

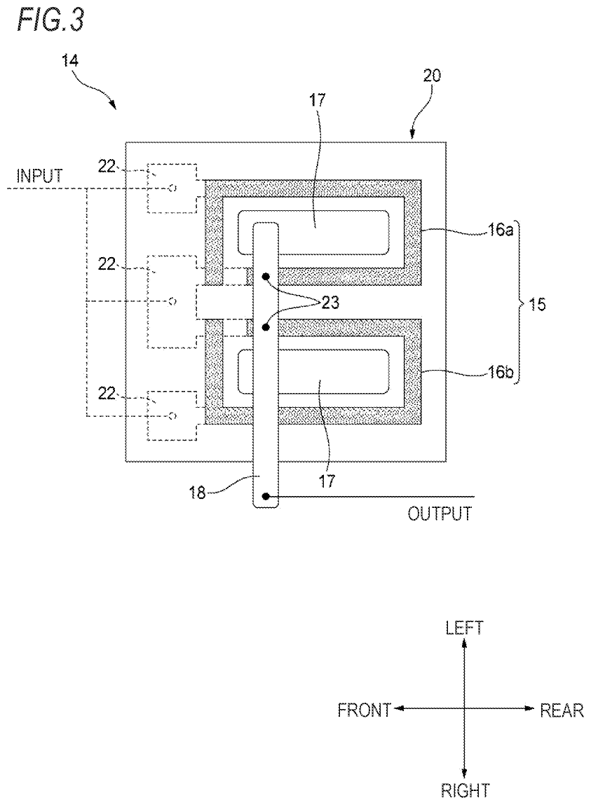

For convenience of description, “front-rear direction”, “up-down direction”, and “left-right direction” are defined as illustrated in FIGS. 2 and 3. The “front-rear direction”, “up-down direction”, and “left-right direction” are orthogonal to each other. The up-down direction coincides with the up-down direction of the vehicle in which the power supply device 1 is mounted.

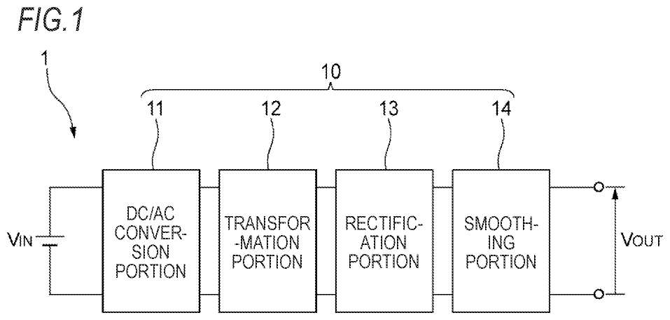

As shown in FIGS. 1 and 3, the power supply device 1 includes an electronic component unit 10 and a circuit board 20 on which the electronic component unit 10 is mounted. For convenience of explanation, FIG. 3 shows only the schematic structure of an inductor portion 15 of the electronic component unit 10. The circuit board 20 on which the electronic component unit 10 is mounted is housed in a metal housing (not shown).

The electronic component unit 10 is a switching type DC/DC converter that achieves the power conversion function described above. Specifically, the electronic component unit 10 includes a DC/AC conversion portion 11, a transformation portion 12, a rectification portion 13, and a smoothing portion 14, as shown in FIG. 1. The DC/AC conversion portion 11 includes, for example, a plurality of switching transistors, and functions to convert the input DC voltage Vin (input voltage, for example, 240 V) to AC voltage.

The transformation portion 12 includes, for example, a transformer, and functions to transform the AC voltage converted by the DC/AC conversion portion 11. The rectification portion 13 includes, for example, a plurality of rectifier diodes, and functions to rectify the AC voltage transformed by the transformation portion 12 into a DC intermittent voltage. The smoothing portion 14 includes an inductor portion 15 (refer to FIG. 3) and an output capacitor (not shown), and functions to smooth the DC intermittent voltage rectified by the rectification portion 13, remove noise, and output an output DC voltage Vout (target voltage, for example, 12 V).

The circuit board 20 has a multilayer structure in which a plurality of layers are stacked in the thickness direction (up-down direction) (also refer to FIG. 2). Note that the circuit board 20 may have a multilayer structure at a location where the inductor portion 15 (a part of the smoothing portion 14) of the electronic component unit 10 is mounted, and may have a single-layer structure or a multilayer structure at a part where the electronic component unit 10 other than the inductor portion 15 is mounted.

In the present example, as shown in FIG. 2, at the location of the circuit board 20 where the inductor portion 15 is mounted, a multilayer structure in which five layers 20a, 20b, 20c, 20d, and 20e are laminated in this order from bottom to top is provided. On the upper surface of each of the five layers 20a to 20e, a pair of conductor patterns 21 having a predetermined symmetrical shape are formed to be aligned in the left-right direction (that is, along the board surface of the circuit board 20). The conductor pattern 21 is made of copper foil, for example.

The end portions of the pair of conductor patterns 21 formed on the lowermost layer 20a function as input ends 22 of the inductor portion 15. In the example shown in FIG. 2, the input ends 22 at three locations aligned at intervals in the left-right direction are conductively connected to each other by the conductor pattern 21. On the other hand, the end portions of the pair of conductor patterns 21 formed on the uppermost layer 20e function as the pair of output ends 23 of the inductor portion 15. In each of the four layers 20b, 20c, 20d, and 20e, vias 24 which are conductively connected to the upper and lower surfaces of the layers are formed at predetermined locations of the pair of conductor patterns 21.

By laminating the five layers 20a, 20b, 20c, 20d, and 20e having the above configuration from bottom to top in this order, as shown in FIG. 3, a first turning portion 16a and a second turning portion 16b are configured in a state of being arranged adjacent to each other in the left-right direction. The first turning portion 16a configures an inductor (coil) in the form of a laminated chip inductor that extends from bottom to top while turning in a rectangular and helical shape clockwise when viewed from above by conductively connecting the left conductor patterns 21 of the five layers 20a to 20e with the vias 24 of the four layers 20b to 20e. On the other hand, the second turning portion 16b configures an inductor (coil) in the form of a laminated chip inductor that extends from bottom to top while turning in a rectangular and helical shape counterclockwise when viewed from above by conductively connecting the right conductor patterns 21 of the five layers 20a to 20e with the vias 24 of the four layers 20b to 20e.

As such, in the inductor portion 15, the first turning portion 16a having a spirally turning shape and the second turning portion 16b having a shape that spirally turn in a direction opposite to that of the first turning portion 16a are arranged adjacent to each other. Since the input end 22 of the first turning portion 16a and the input end 22 of the second turning portion 16b are conductively connected to each other as described above, the input ends 22 are configured to receive a common input.

Therefore, when the inductor portion 15 is energized, magnetic fields in opposite directions are generated at the same timing in the first turning portion 16a and the second turning portion 16b. In the present example, since the first turning portion 16a and the second turning portion 16b have a symmetrical shape, the strength of the generated magnetic field is also the same. Since both magnetic fields are generated close to each other, at least some of the magnetic fields emitted to the outside (distantly) cancel each other out. As a result, the radiation noise emitted by the inductor portion 15 is reduced as a whole. Since it is considered that the magnetic fields generated inside the turns of the first turning portion 16a and the second turning portion 16b are not affected by the cancellation, the original function of the inductor portion 15 is not excessively impaired.

Compared to the case where a single inductor is used as the inductor portion 15, the input current is divided between the first turning portion 16a and the second turning portion 16b, and thus the overall amount of heat generated in the inductor portion 15 is reduced. This is based on the fact that the amount of heat generated by an inductor is generally proportional to the loss and proportional to the square of the current value of the input current to the inductor. By reducing the amount of heat generated, the operation of the inductor portion 15 itself and other components of the electronic component unit 10 can be maintained more appropriately. The thickness of the electronic component unit 10 can be reduced compared to the case where a separate inductor is soldered onto the board surface of the circuit board 20. Productivity is excellent as a soldering step is not required.

As shown in FIG. 3, core materials 17 are placed on the upper surface of the circuit board 20 at positions corresponding to the inside of the turns of each of the first turning portion 16a and the second turning portion 16b. The core material 17 is composed of, for example, a magnetic thin plate extending in the front-rear direction. By disposing the core materials 17 in each of the first turning portion 16a and the second turning portion 16b as such, the inductance of each of the first turning portion 16a and the second turning portion 16b can be increased.

As shown in FIG. 3, a rod-shaped metal bus bar 18 extending in the left-right direction is soldered from above to the output end 23 of each of the first turning portion 16a and the second turning portion 16b. Thereby, the output end 23 of each of the first turning portion 16a and the second turning portion 16b and the bus bar 18 are conductively connected. As a result, the output current from the inductor portion 15 can be obtained via the bus bar 18 without requiring soldering of lead wires or the like for output from the inductor portion 15.

The bus bar 18 is also in pressing contact from above with the pair of core materials 17 positioned inside the respective turns of the first turning portion 16a and the second turning portion 16b. The bus bar 18 may have a projection or the like for pressing contact with the core material 17. As a result, the pair of core materials 17 are fixed to the circuit board 20 by being pressed and clamped in the up-down direction by the circuit board 20 and the bus bars 18. Accordingly, a complicated mounting step to the circuit board 20 is not required to fix the core material 17 to the circuit board 20.

As described above, according to the power supply device 1 according to the present embodiment, the electronic component unit 10 mounted on the circuit board 20 includes the laminated inductor portion 15 inside the circuit board 20. The inductor portion 15 is configured such that the first turning portion 16a having a spirally turning shape and the second turning portion 16b having a shape that spirally turns in a direction opposite to that of the first turning portion 16a are arranged adjacent to each other, and a common input is made to the input end 22 of the first turning portion 16a and the input end 22 of the second turning portion 16b. Therefore, when the inductor portion 15 is energized, magnetic fields in opposite directions can be generated in the first turning portion 16a and the second turning portion 16b at the same timing. Since both magnetic fields are generated close to each other, at least some of the magnetic fields emitted to the outside (distantly) cancel each other out. As a result, the radiation noise emitted by the inductor portion 15 is reduced as a whole. Therefore, the power supply device 1 according to the present embodiment can reduce radiation noise.

Compared to the case where a single inductor is used as the inductor portion 15, the input current is divided between the first turning portion 16a and the second turning portion 16b, and thus the overall amount of heat generated in the inductor portion 15 is reduced. By reducing the amount of heat generated, the operation of the inductor portion 15 and other components of the electronic component unit 10 can be maintained more appropriately. The thickness of the electronic component unit 10 can be reduced compared to the case where a separate inductor soldered onto the board surface of the circuit board 20 is used. Productivity is excellent as a soldering step is not required.

The core materials 17 are placed on the board surface to correspond to each of the first turning portion 16a and the second turning portion 16b. For example, a magnetic thin plate can be used for the core material 17. As a result, the inductance of the inductor portion 15 can be increased without requiring a complicated mounting step for providing the core material 17.

The bus bar 18 is soldered to the output end 23 of the first turning portion 16a and the output end 23 of the second turning portion 16b. As a result, the output current from the inductor portion 15 is obtained via the bus bar 18 without requiring soldering of lead wires for output from the inductor portion 15.

The bus bar 18 is not only soldered to the output ends 23 of the first turning portion 16a and the second turning portion 16b, but also comes into contact with the pair of core materials 17. Thereby, the bus bar 18 for the output from the inductor portion 15 can also be used for fixing the pair of core materials 17.

The inductor portion 15 is used for removing noise from the current after transformation by the transformation portion 12 (refer to FIG. 1) and for smoothing the current. By using the inductor portion 15 according to the present embodiment for processing the current after transformation, which particularly requires noise removal and smoothing in the electronic component unit 10 having a voltage conversion function, the function of reducing the radiation noise and the amount of heat generated by the inductor portion 15 can be exhibited more effectively.

The present invention is not limited to each of the above-described embodiments, and various modification examples can be adopted within the scope of the present invention. For example, the present invention is not limited to the above-described embodiments, and appropriate modifications, improvements, and the like are possible. Any material, shape, dimensions, number, location, and the like of each configuration element in the above-described embodiments can be adopted as long as the present invention can be exhibited, and are not limited.

In the above embodiment, the core material 17 is placed on the board surface to correspond to each of the first turning portion 16a and the second turning portion 16b. However, the core material 17 may not be placed.

In the above embodiment, the pair of core materials 17 are fixed to the circuit board 20 as the bus bar 18 also comes into contact with the pair of core materials 17. However, the bus bar 18 may not have to be in contact with the pair of core materials 17. Here, a complicated mounting step to the circuit board 20 is required to fix the core material 17 to the circuit board 20.

In the above-described embodiment, the power supply device 1 converts an input DC voltage into a predetermined DC voltage and outputs the converted voltage. On the other hand, the power supply device 1 may be configured to convert an input AC voltage into a predetermined DC voltage or AC voltage and output the converted voltage, or may be configured to convert an input DC voltage to a predetermined AC voltage and output the converted voltage.

Here, in the embodiment of the power supply device 1 according to the present invention described above, there is provided a power supply device (1) including:
an electronic component unit (10) having a voltage conversion function that converts an input voltage (Vin) into a predetermined target voltage (Vout) and outputs the converted voltage; and a circuit board (20) on which the electronic component unit (10) is mounted, in which:
the circuit board (20) has, at least at a part thereof, a multilayer structure in which a plurality of layers (20a to 20e) are stacked in a thickness direction of the circuit board (20); and
the electronic component unit (10) includes an inductor portion (15) configured such that a first turning portion (16a) configured by a conductor pattern (21) divided and wired into the plurality of layers (20a to 20e) to have a spirally turning shape, and a second turning portion (16b) configured by a conductor pattern (21) divided and wired into the plurality of layers (20a to 20e) to have a shape that spirally turns in a direction opposite to that of the first turning portion (16a), are arranged adjacent to each other in a direction along a board surface of the circuit board (20), and a common input is made to an input end (22) of the first turning portion (16a) and an input end (22) of the second turning portion (16b).

According to the power supply device configured as described above, the electronic component unit includes the laminated inductor portion configured in the circuit board having a multilayer structure. The inductor portion is configured such that the first turning portion having a spirally turning shape and the second turning portion having a shape that spirally turns in a direction opposite to that of the first turning portion are arranged adjacent to each other, and a common input is made to the input end of the first turning portion and the input end of the second turning portion. Therefore, when the inductor portion is energized, magnetic fields in opposite directions can be generated in the first turning portion and the second turning portion at the same timing. Since the magnetic fields are generated close to each other, at least some of the magnetic fields emitted to the outside (distantly) of the inductor portion cancel each other out. As a result, radiation noise emitted from the inductor portion is reduced as a whole. Since it is considered that the magnetic fields generated inside the turns of the first turning portion and the second turning portion are not affected by the cancellation, the original functions of the inductor portion (for example, reduction of conduction noise, or signal smoothing) are not excessively impaired. Therefore, the power supply device having such configuration can reduce radiation noise.

The power supply device configured as described above also has other effects. For example, since the input current is divided into the plurality of turning portions, the overall amount of heat generated in the inductor portion will be reduced compared to using a single inductor. This is because the amount of heat generated by an inductor is generally proportional to the loss and proportional to the square of the current value of the input current to the inductor. By reducing the amount of heat generated, the operation of the inductor portion itself and other components of the electronic component unit can be maintained more appropriately. The thickness of the electronic component unit can be reduced compared to the case where a separate inductor is soldered onto the circuit board. Productivity is excellent as a soldering step is not required.

The electronic component unit (10) may further include a first core material (17) placed on the board surface to be positioned inside turns of the first turning portion (16a), and a second core material (17) placed on the board surface to be positioned inside turns of the second turning portion (16b).

According to the power supply device configured as described above, the core material is placed on the board surface to correspond to each of the first turning portion and the second turning portion. For example, a magnetic thin plate can be used for the core material. As a result, the inductance of the inductor portion can be increased without requiring a complicated mounting step for providing the core material.

The electronic component unit (10) may further include a bus bar (18) soldered to an output end (23) of the first turning portion (16a) and the output end (23) of the second turning portion (16b).

According to the power supply device configured as described above, the bus bar is soldered to the output end of the first turning portion and the output end of the second turning portion. As a result, the output current from the inductor portion is obtained via the bus bar without requiring soldering of lead wires for output from the inductor portion. Therefore, it is possible to improve the productivity of the power supply device.

The bus bar (18) may further come into contact with the first core material (17) and the second core material (17).

According to the power supply device configured as described above, the bus bar is not only soldered to the output ends of the first turning portion and the second turning portion, but also comes into contact with the first core material and the second core material. Thereby, the bus bar for the output from the inductor portion can also be used for fixing the first core material and the second core material. Therefore, it is possible to reduce the size and cost of the power supply device.

The inductor portion (15) may be disposed in the electronic component unit (10) to remove noise from a current after transformation.

According to the power supply device configured as described above, the inductor portion is used to remove noise from the current after transformation. By using the inductor portion having such configuration for processing the current after transformation, which particularly requires noise removal and smoothing in the electronic component unit having a voltage conversion function, the function of reducing the radiation noise and the amount of heat generated by the inductor portion can be exhibited more effectively.

The present application is based on Japanese Patent Application (No. 2021-185739) filed on Nov. 15, 2021, and the content thereof is incorporated herein by reference.

### INDUSTRIAL APPLICABILITY

A power supply device of the present invention includes an inductor capable of reducing radiation noise. The present invention having such effect can be used, for example, as a DC/DC converter for power conversion between a battery and an inverter mounted in a vehicle such as a hybrid vehicle.

### REFERENCE SIGNS LIST

1: Power supply device
10: Electronic component unit
15: Inductor portion
16a: First turning portion
16b: Second turning portion
17: Core material (first core material, second core material)
18: Bus bar
20: Circuit board
20a to 20e: Layer
21: Conductor pattern
22: Input end
23: Output end

1. A power supply device comprising:
an electronic component unit having a voltage conversion function that converts an input voltage into a predetermined target voltage and outputs the converted voltage; and
a circuit board on which the electronic component unit is mounted, wherein:
the circuit board has, at least at a part thereof, a multilayer structure in which a plurality of layers are stacked in a thickness direction of the circuit board; and
the electronic component unit includes an inductor portion configured such that a first turning portion configured by a conductor pattern divided and wired into the plurality of layers to have a spirally turning shape, and a second turning portion configured by a conductor pattern divided and wired into the plurality of layers to have a shape that spirally turns in a direction opposite to that of the first turning portion, are arranged adjacent to each other in a direction along a board surface of the circuit board, and a common input is made to an input end of the first turning portion and an input end of the second turning portion.

2. The power supply device according to claim 1, wherein
the electronic component unit further includes a first core material placed on the board surface to be positioned inside turns of the first turning portion, and a second core material placed on the board surface to be positioned inside turns of the second turning portion.

3. The power supply device according to claim 2, wherein
the electronic component unit further includes a bus bar soldered to an output end of the first turning portion and the output end of the second turning portion.

4. The power supply device according to claim 3, wherein
the bus bar further comes into contact with the first core material and the second core material.

5. The power supply device according to claim 1, wherein
the inductor portion is disposed in the electronic component unit to remove noise from a current after transformation.
